(19) United States
(12) Patent Application Publication
(10) Pub. No.: US 2017/0363488 A1
(43) Pub. Date: Dec. 21, 2017

(54) PROTECTIVE ELECTRODE FOR A PIEZOCERAMIC SENSOR

(71) Applicant: CeramTec GmbH, Plochingen (DE)

(72) Inventor: Hans-Jürgen SCHREINER, Hersbruck (DE)

(21) Appl. No.: 15/501,744

(22) PCT Filed: Aug. 4, 2015
(86) PCT No.: PCT/EP2015/067909

§ 371 Date: Jul. 18, 2017

(30) Foreign Application Priority Data
Aug. 4, 2014 (DE) 10 2014 215 323.9

(51) Int. Cl. G01L 1/16; H01L 41/047; H01L 41/04; H01L 41/113; G01P 15/09

(52) U.S. Cl. CPC G01L 1/16; H01L 41/1132; G01P 15/09; H01L 41/042; H01L 41/047

(57) ABSTRACT

The invention relates to a piezoceramic sensor in a housing having a layer (3), preferably a PZT layer, made of a piezoelectric material, on both sides of which there is a respective sensor electrode (2), both sensor electrodes (2) being connected in each case to a pole (5, 6). In order that no potential difference, which would allow for the charge to be dissipated by way of the surface, is formed between the housing and the sensor electrodes (2), it is proposed according to the invention that the layer (3) protrudes beyond the sensor electrode (2) on at least one side of the layer (3), and a protective electrode (1) which encompasses the sensor electrode (2) at an insulating distance (7) is arranged on that part of the layer (3) which protrudes beyond the sensor electrode (2).

The invention relates to a piezoceramic sensor in a housing having a layer made from a piezoelectric material, on both sides of which is located a sensor electrode, and both sensor electrodes are in each case connected to a pole.

Sensors of this kind are used, for example, for pressure measurement. They are flat and very accurate.

It is of disadvantage that a potential difference, which enables the charge to be dissipated over the surface, is formed between the sensor electrodes and the housing. The accuracy of the sensor would then be limited.

The invention is based on the object of improving a piezoceramic sensor in accordance with the pre-characterizing clause of claim 1 such that no potential difference, which would enable the charge to be dissipated over the surface, occurs between the housing and the sensor electrodes.

According to the invention, this object is achieved in that the layer protrudes beyond the sensor electrode on at least one side of the layer, and a protective electrode which encompasses the sensor electrode at an insulating distance is arranged on the part of the layer which protrudes beyond the sensor electrode. The same charge as on the sensor electrodes is induced on the protective electrode/protective electrodes; there is therefore no potential difference which would enable the charge to be dissipated over the surface. There remains the discharge over the volume, wherein the volume resistances are so large that the measurement is unaffected. The protective electrode therefore serves to prevent a voltage equalization between the sensor housing and the sensor electrodes. The smallest deformations in the μm and sub-μm range can be measured with this sensor. In doing so, the protective electrode prevents dissipation of the charge.

Moisture, which can occur on the surface in spite of mounting the sensor in a casting compound, leads to an increase in the conductivity, particularly with piezoelectric materials. However, as the potential difference between protective- and sensor electrode is equal to zero, there is also no voltage equalization between protective- and sensor electrode.

Preferably, both the sensor electrode and the protective electrode are made from a sintered silver paste.

In a preferred embodiment, the sensor electrode covers only an internal radius of the layer, and the protective electrode encompasses the sensor electrode coaxially at an insulating distance. This coaxial embodiment requires the least installation space.

Preferably, the layer is circular in shape and is made from a ceramic based on polycrystalline ferroelectric lead zirconate titanate (PZT).

In an embodiment, the protective electrode is located on both sides of the layer. This embodiment best prevents a potential difference.

In an alternative embodiment, the protective electrode is located only on one side of the layer. Here, the sensor electrode preferably completely covers the layer on the other side, which is not provided with the protective electrode. A potential difference is also prevented in this embodiment.

Use of the sensor according to the invention for measuring pressures is preferred. Advantageous in injectors for automobiles.

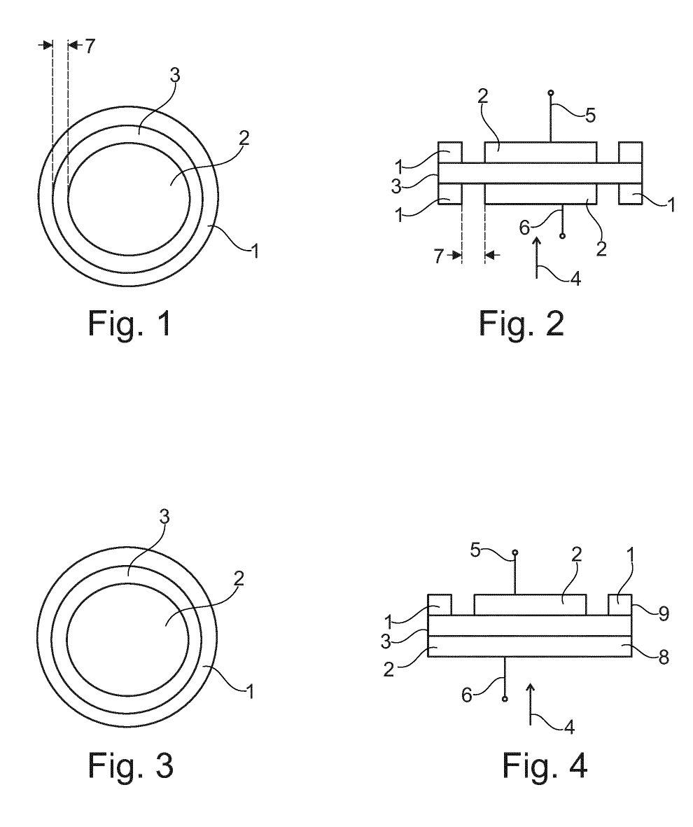

FIG. 1 shows an embodiment of a ceramic sensor according to the invention in plan view and FIG. 2 shows this sensor in a side view. A layer 3 (in this embodiment designed as a disk) is made from a ceramic material based on polycrystalline ferroelectric lead zirconate titanate. A sensor electrode 2 is sintered on both sides with this layer 3, wherein the sensor electrode 2 only covers an internal radius of the layer 3, i.e. the layer 3 protrudes in the form of a ring beyond the layer 3. A protective electrode 1 is arranged on this ring-shaped region, which protrudes over the layer 3, on both sides of the layer 3 at an insulating distance 7 from the sensor electrode 2. The protective electrode 1 is designed in the form of a ring and, in this embodiment, is located both above and below the layer 3. FIG. 1 shows the sensor according to FIG. 2 in plan view. It can be clearly seen that the ring-shaped protective electrode 1 encompasses the sensor electrode 2 coaxially at an insulating distance 7. The sensor electrodes 2 on both sides of the layer 3 are in each case connected to a pole 5, 6. As there is no potential difference between the sensor electrode 2 and the protective electrode 1, there is also no charge flow. If a force 4 (see FIG. 2) is exerted on the sensor, it shortens or bends and this shortening or bending can be measured with the sensor.

An alternative embodiment of a ceramic sensor according to the invention is shown in FIGS. 3 and 4. FIG. 3 shows this alternative sensor in plan view, and FIG. 4 in a side view. The top side 9, on which the protective electrode 1 is located, is identical to the embodiment according to FIGS. 1 and 2. FIG. 3 is therefore identical to FIG. 1. However, in this embodiment, the bottom side 8 of the sensor is designed as a sensor electrode 2 over the whole surface, i.e. there is no protective electrode 1 on the bottom side 8 of the sensor as on the top side 9.

In both embodiments of the sensor according to the invention, said sensor is encompassed by a housing (not shown in the figures). The housing can also be an overmolded plastic. For insulation purposes, the protective electrode 1 can be covered with an insulating layer. The protective electrode 1 is preferably made from an applied sintered silver paste.

1. A piezoceramic sensor in a housing having a layer, preferably a PZT layer, made from a piezoelectric material, on both sides of which is located a sensor electrode, and both sensor electrodes are in each case connected to a pole, characterized in that the layer protrudes beyond the sensor electrode on at least one side of the layer, and a protective electrode which encompasses the sensor electrode at an insulating distance is arranged on the part of the layer which protrudes beyond the sensor electrode.

2. The sensor according to claim 1, wherein both the sensor electrode and the protective electrode are made from a sintered silver paste.

3. The sensor according to claim 1, wherein the sensor electrode covers only an internal radius of the layer, and the protective electrode encompasses the sensor electrode coaxially at an insulating distance.

4. The sensor according to claim 1, wherein the layer (3) is circular in shape and is made from a ceramic based on polycrystalline ferroelectric lead zirconate titanate.

5. The sensor according to claim 1, wherein the protective electrode is located on both sides of the layer.

6. The sensor according to claim 1, wherein the protective electrode is located only on one side of the layer.

7. The sensor according to claim 6, wherein the sensor electrode completely covers the layer on the other side, which is not provided with the protective electrode.

8. The use of a sensor according to claim 1 for measuring pressures.

9. The use of a sensor according to claim 7 in injectors for automobiles.

10. A method for measuring pressure, comprising measuring pressure with the sensor according to claim 1.

11. An injector for an automobile, comprising the sensor according to claim 1.
